(19) United States
(12) Patent Application Publication
(10) Pub. No.: US 2024/0021761 A1
(43) Pub. Date: Jan. 18, 2024

(54) ELECTRONIC DEVICE

(71) Applicant: InnoLux Corporation, Miao-Li County (TW)

(72) Inventors: Tung-Chang TSAI, Miao-Li County (TW); Chih-Chin WANG, Miao-Li County (TW)

(21) Appl. No.: 18/334,657

(22) Filed: Jun. 14, 2023

(30) Foreign Application Priority Data
Jul. 14, 2022 (CN) 202210829889.9

(51) Int. Cl. H01L 33/58; H01L 25/16; H01L 33/62; H01L 33/38

(52) U.S. Cl. CPC H01L 33/58; H01L 25/167; H01L 33/62; H01L 33/38

(57) ABSTRACT

An electronic device includes a substrate, a driving component and an electronic component. The driving component is arranged on the substrate, wherein the driving component includes a first electrode and a first optical adjustment unit, the first optical adjustment unit is arranged on the first electrode, and the first optical adjustment unit has a first opening to expose a surface of the first electrode. The electronic component is arranged on the driving component, wherein the electronic component includes a second electrode electrically connected to the first electrode of the driving component through the first opening of the first optical adjustment unit.

### CROSS-REFERENCE TO RELATED APPLICATIONS

This application claims the benefits of the Chinese Patent Application Serial Number 202210829888.9, filed on Jul. 14, 2022, the subject matter of which is incorporated herein by reference.

### BACKGROUND

### Field of the Disclosure

The present disclosure relates to an electronic device and, more particularly, to an electronic with optical adjustment units.

### Description of Related Art

With the continuous advancement of technology and in response to the usage habits of users, it is still necessary to continuously improve the display device. At present, in the display device, the metal layer is prone to reflect light, resulting in problems such as glare that interferes with vision or lowers the contrast of the display device, thereby affecting the display quality.

Therefore, there is an urgent need to develop an electronic device in order to mitigate and/or obviate the aforementioned defects.

### SUMMARY

The present disclosure provides an electronic device, which includes a substrate; a driving component arranged on the substrate, wherein the driving component includes a first electrode and a first optical adjustment unit, the first optical adjustment unit is arranged on the first electrode, and the first optical adjustment unit has a first opening to expose a surface of the first electrode; and an electronic component arranged on the driving component, wherein the electronic component includes a second electrode electrically connected to the first electrode of the driving component through the first opening of the first optical adjustment unit.

Other novel features of the disclosure will become more apparent from the following detailed description when taken in conjunction with the accompanying drawings.

### BRIEF DESCRIPTION OF DRAWINGS

FIG. 1A is a top view of part of the electronic device according to an embodiment of the present disclosure;

FIG. 1B is a cross-sectional view of the electronic device of FIG. 1A taken along line I-I′;

FIG. 2 is a cross-sectional view of the electronic device according to another embodiment of the present disclosure; and

FIG. 3 shows the reflectivity analysis results for the combination structure of the first electrode and the optical adjustment unit according to an embodiment of the present disclosure.

### DETAILED DESCRIPTION OF EMBODIMENT

Reference will now be made in detail to exemplary embodiments of the present disclosure, examples of which are illustrated in the accompanying drawings. Wherever possible, the same reference numerals are used in the drawings and description to refer to the same or like parts.

Throughout the specification and the appended claims, certain terms may be used to refer to specific components. Those skilled in the art will understand that electronic device manufacturers may refer to the same components by different names. The present disclosure does not intend to distinguish between components that have the same function but have different names. In the following description and claims, words such as “containing” and “comprising” are open-ended words, and should be interpreted as meaning “including but not limited to”.

Directional terms mentioned in the specification, such as “up”, “down”, “front”, “rear”, “left”, “right”, etc., only refer to the directions of the drawings. Accordingly, the directional term used is illustrative, not limiting, of the present disclosure. In the drawings, various figures illustrate the general characteristics of methods, structures and/or materials used in particular embodiments. However, these drawings should not be construed to define or limit the scope or nature encompassed by these embodiments. For example, the relative sizes, thicknesses and positions of various layers, regions and/or structures may be reduced or enlarged for clarity.

One structure (or layer, component, substrate) described in the present disclosure is disposed on/above another structure (or layer, component, substrate), which can mean that the two structures are adjacent and directly connected, or can refer to two structures that are adjacent rather than directly connected. Indirect connection means that there is at least one intermediate structure (or intermediate layer, intermediate component, intermediate substrate, intermediate space) between the two structures, the lower surface of one structure is adjacent to or directly connected to the upper surface of the intermediate structure, and the upper surface of the other structure is adjacent to or directly connected to the lower surface of the intermediate structure. The intermediate structure may be a single-layer or multi-layer physical structure or a non-physical structure, which is not limited. In the present disclosure, when a certain structure is arranged “on” other structures, it may mean that a certain structure is “directly” on other structures, or it means that a certain structure is “indirectly” on other structures; that is, at least one structure is sandwiched, in between a certain structure and other structures.

The terms, such as “about”, “equal to”, “equal” or “same”, “substantially”, or “substantially”, are generally interpreted as within 20% of a given value or range, or as within 10%, 5%, 3%, 2%, 1%, or 0.5% of a given value or range.

In the specification and claims, unless otherwise specified, ordinal numbers, such as “first” and “second”, used herein are intended to distinguish elements rather than disclose explicitly or implicitly that names of the elements bear the wording of the ordinal numbers. The ordinal numbers do not imply what order an element and another element are in terms of space, time or steps of a manufacturing method. Thus, what is referred to as a “first element” in the specification may be referred to as a “second element” in the claims.

In the present disclosure, the measurement method of length, height and angle may be obtained by using an optical microscope, and the length, height and angle may be obtained by measuring the cross-sectional image in an electron microscope, but it is not limited thereto. In addition, the terms “the given range is from the first numerical value to the second numerical value” and “the given range falls within the range from the first numerical value to the second numerical value” mean that the given range includes the first numerical value, the second numerical value and other values in between the first and second numerical values.

It is noted that the following are exemplary embodiments of the present disclosure, but the present disclosure is not limited thereto, while a feature of some embodiments can be applied to other embodiments through suitable modification, substitution, combination, or separation. In addition, the present disclosure can be combined with other known structures to form further embodiments.

Unless otherwise defined, all terms (including technical and scientific terms) used herein have the same meaning as commonly understood by those skilled in the art related to the present disclosure. It can be understood that these terms, such as those defined in commonly used dictionaries, should be interpreted as having meaning consistent with the relevant technology and the background or context of the present disclosure, and should not be interpreted in an idealized or excessively formal way, unless there is a special definition in the embodiment of the present disclosure.

In this disclosure, the electronic device may include a display device, a backlight device, an antenna device, a sensing device or a tiled device, but it is not limited thereto. The electronic device may be a bendable or flexible electronic device. The display device may be a non-self-luminous display device or a self-luminous display device. The antenna device may be a liquid crystal type antenna device or a non-liquid crystal type antenna device, and the sensing device may be a sensing device for sensing capacitance, light, thermal energy or ultrasonic waves, but it is not limited thereto. In the present disclosure, the electronic device may include electronic components, and the electronic components may include passive components and active components, such as capacitors, resistors, inductors, diodes, transistors, and the like. The diodes may include light emitting diodes or photodiodes. The light emitting diodes may, for example, include organic light emitting diodes (OLEDs), sub-millimeter light emitting diodes (mini LEDs), micro light emitting diodes (micro LEDs) or quantum dot light emitting diodes (quantum dot LEDs), but it is not limited to. The tiled device may be, for example, a tiled display device or a tiled antenna device, but it is not limited thereto. It is noted that the electronic device may be any permutation and combination of the aforementioned, but it is not limited thereto. In the following description, a display device is used as an electronic device to illustrate the content of the disclosure, but the present disclosure is not limited thereto.

FIG. 1A is a top view of part of the electronic device according to an embodiment of the present disclosure. FIG. 1B is a cross-sectional view of the electronic device of FIG. 1A taken along line I-I′.

As shown in FIG. 1A and FIG. 1B, the electronic device 1 of this embodiment may include: a substrate 10; a driving component D arranged on the substrate 10; and an electronic component 20(G) arranged on the driving component D, wherein the electronic component 20(G) is electrically connected to the driving component D.

In more detail, as shown in FIG. 1B, the electronic device 1 of this embodiment may include: a substrate 10; a first insulation layer 111 arranged on the substrate 10; a buffer layer 112 arranged on the first insulation layer 111; a semiconductor layer 113 arranged on the buffer layer 112; a gate insulation layer 114 arranged on the semiconductor layer 113; a gate layer 115 arranged on the gate insulation layer 114; a second insulation layer 116 arranged on the gate layer 115; a source-drain layer 117 arranged on the second insulation layer 116 and electrically connected to the semiconductor layer 113, wherein the source-drain layer 117 includes a first electrode E1 and a third electrode E2; a first optical adjustment unit 12 and a second optical adjustment unit 12′ respectively arranged on the source-drain layer 117, wherein the first optical adjustment unit 12 has a first opening H1 to expose partial surface 1171 of the first electrode E1; and a passivation layer 118 arranged on the first optical adjustment unit 12 and the second optical adjustment unit 12′. According to some embodiments, the first electrode E1 may be a drain, and the third electrode E2 may be a source. In this embodiment, the driving component D includes: a first electrode E1 and a first optical adjustment unit 12, wherein the first optical adjustment unit 12 is arranged on the first electrode E1, and the first optical adjustment unit 12 has an opening H1 to expose the surface of the first electrode E1. In detail, the driving component D includes a semiconductor layer 113, a gate layer 115, a source-drain layer 117, a first optical adjustment unit 12 and a second optical adjustment unit 12′, but the structure of the driving component D in the present disclosure is not limited to that shown in FIG. 1B. For example, in this embodiment, the driving component D may be a thin film transistor, such as a top gate transistor. However, in another embodiment of the present disclosure, the driving component D may be a bottom gate transistor or a double gate (or dual gate) transistor, but the present disclosure is not limited thereto.

In the present disclosure, the substrate 10 may be a rigid substrate or a flexible substrate. The material of the substrate 10 may include a quartz, a glass, a silicon wafer, a sapphire, polycarbonate (PC), polyimide (PI), polypropylene (PP), polyethylene terephthalate (PET) or other plastic or polymer materials, or a combination thereof, but the present disclosure is not limited thereto. The material of the semiconductor layer 113 may be amorphous silicon, polysilicon (such as low temperature polysilicon (LTPS)), or oxide semiconductor (such as indium gallium zinc oxide (IGZO)), but the present disclosure is not limited thereto. In addition, the materials of the first insulation layer 111, the buffer layer 112, the gate insulation layer 114, and the second insulation layer 116 may respectively include silicon oxide, silicon nitride and silicon oxynitride, or a combination thereof, but the present disclosure is not limited thereto. In the present disclosure, the material of the gate layer 115 and the source-drain layer 117 may be a metal, such as gold (Au), silver (Ag), copper (Cu), aluminum (Al), titanium (Ti), chromium (Cr), molybdenum (Mo), nickel (Ni), or an alloy thereof, or a combination thereof, or other electrode materials, but the present disclosure is not limited thereto. In addition, the gate layer 115 and the source-drain layer 117 may be made of a single layer or multiple layers of metal materials. For example, in this embodiment, the source-drain layer 117 may be made of multi-layer metal materials of Mo/Al/Mo or Ti/Al/Ti. Furthermore, the material of the passivation layer 118 may include silicon oxide, silicon oxynitride, silicon nitride, aluminum oxide, resin, polymer, photoresist material, or a combination thereof, but the present disclosure is not limited thereto.

In this embodiment, as shown in FIG. 1A, the electronic device 1 may include a plurality of electronic components. According to an embodiment, the electronic components may be of different colors, for example, may include electronic components 20(G), 20(R), 20(B), but the present disclosure is not limited thereto. The electronic component 20(G) may emit green light, the electronic component 20(R) may emit red light, and the electronic component 20(B) may emit blue light, but the present disclosure is not limited thereto. According to some embodiments, as shown in FIG. 1B, the electronic component 20(G) is arranged on the passivation layer 118 and may include: a second electrode 211 that is electrically connected to the first electrode E1 of the driving component D through the opening H1 of the first optical adjustment unit 12 and the driving component. In detail, the electronic component 20(G) further includes a light emitting layer 212 and a fourth electrode 213, wherein the dotted line between portions of the second electrode 211 indicates that the portions of the second electrode 211 are connected in another cross-sectional view (not shown). The light emitting layer 212 may be arranged between the second electrode 211 and the fourth electrode 213. For convenience of illustration, the fourth electrode 213 is not shown in FIG. 1A. The second electrode 211 may be electrically connected to the first electrode E1 of the driving component D through the first opening H1 of the first optical adjustment unit 12. The second electrode 211 may be an anode, and the fourth electrode 213 may be a cathode. According to another embodiment, the second electrode 211 may be a cathode, and the fourth electrode 213 may be an anode. A pixel definition layer 13 is arranged on the passivation layer 118 and the second electrode 211, and has a second opening H2 to expose part of the second electrode 211. The light emitting layer 212 is disposed in the second opening H2, and arranged on the second electrode 211. The fourth electrode 213 is arranged on the light emitting layer 212. The second opening H2 of the pixel definition layer 13 defines a light emitting region R of the electronic component 20(G). Although not shown in detail, the electronic component 20(R), 20(B) may also have a structure similar to that of the electronic component 20(G), and thus a detailed description is deemed unnecessary. According to some embodiments, the light emitting layer 212 may be an organic light emitting layer, so that the electronic device 1 may be an organic light emitting display device, but the present disclosure is not limited thereto. In the present disclosure, the electronic component 20(G) is taken as an example mainly for illustration, while other electronic components, such as electronic components 20(R), 20(B), each may also have a structure similar to that of electronic component 20(G) and may also have an electrical connection configuration similar to other driving components (not shown, similar to driving component D). For example, according to some embodiments, the electronic device may include a plurality of driving components and a plurality of electronic components, wherein the plurality of driving components may be arranged on the substrate 10, and the plurality of electronic components may be arranged on the plurality of driving components. The plurality of driving components may include another driving component, and the plurality of electronic components may include another electronic component. Similar to the connection configuration of the electronic component 20(G) shown in FIG. 1B, although not shown, another electronic component (for example, 20(R)) may be correspondingly arranged on another driving component D that may include the first electrode E1 and the first optical adjustment unit 12, while another electronic component may include a second electrode 211. The first optical adjustment unit 12 may be arranged on the first electrode E1, and has an opening H1 to expose the surface of the first electrode E1. The second electrode 211 of another electronic component 20(R) may be electrically connected to the first electrode E1 of another driving component D through the opening H1 of the first optical adjustment unit 12.

According to some embodiments, the electronic component may be used as a sub-pixel, and a plurality of electronic components (sub-pixels) of different colors may be combined to form a pixel unit. For example, as shown in FIG. 1A, three electronic components 20(R), 20(B) and 20(G) of different colors may form a pixel unit. According to some embodiments, as shown in FIG. 1B, the area of the fourth electrode 213 may be larger than the area of the second electrode 211. The fourth electrode 213 may be arranged on at least one sub-pixel (such as 20(G)). According to some embodiments, although not shown, the fourth electrode 213 may be arranged on a plurality of sub-pixels, for example, arranged on the sub-pixels 20(R), and 20(G). According to some embodiments, although not shown, the fourth electrode 213 may be arranged on a plurality of pixel units.

In the present disclosure, the electronic components 20(G), 20(R), may include organic light emitting diodes (OLEDs), quantum dot light emitting diodes (QDLED/QLED), fluorescence, phosphor, light emitting diodes (LEDs), micro light emitting diodes (micro LEDs), mini light emitting diodes (mini LEDs), but the present disclosure is not limited thereto. Therefore, the electronic device 1 of the present disclosure may be applied to any electronic device that requires a display screen, such as monitors, mobile phones, notebook computers, video cameras, still cameras, music players, mobile navigators, TV sets and other electronic devices that display images. In addition, when the electronic device is a tiled display system, the electronic device may be applied to any electronic device that needs to display a large image, such as a video wall or a billboard, but the present disclosure is not limited thereto.

In the present disclosure, the materials of the second electrode 211 and the fourth electrode 213 each may be metal, metal oxide, or a combination thereof. The suitable metallic materials include gold (Au), silver (Ag), copper (Cu), aluminum (Al), titanium (Ti), chromium (Cr), molybdenum (Mo), nickel (Ni), or an alloy thereof, or a combinations thereof, but the present disclosure is not limited thereto. The suitable metal oxide materials include indium tin oxide (ITO), aluminum zinc oxide (AZO), indium gallium zinc oxide (IGZO), antimony tin oxide, ATO), fluorine-doped tin oxide (FTO), or a combination thereof, but the present disclosure is not limited thereto. In addition, the second electrode 211 and the fourth electrode 213 may be composed of single-layer or multi-layer materials; for example, in this embodiment, the second electrode 211 may be composed of multi-layer materials of ITO/Ag/ITO. Moreover, in one embodiment of the present disclosure, the second electrode 211 may be a reflective electrode, such as a reflective electrode including a metal material, and the fourth electrode 213 may be a transparent electrode, such as a transparent electrode including a transparent metal oxide.

In the present disclosure, as shown in FIG. 1B, the first optical adjustment unit 12 may include an insulation layer 121 and a metal layer 122, and the insulation layer 121 is arranged between the first electrode E1 and the metal layer 122. Similarly, the second optical adjustment unit 12′ may include an insulation layer 121 and a metal layer 122, wherein the insulation layer 121 is arranged between the source-drain layer 117 and the metal layer 122. More specifically, the insulation layer 121 is arranged between the first electrode E1 or the third electrode E2 and the metal layer 122. In the electronic device 1 of the present disclosure, the first optical adjustment unit 12 is arranged on the first electrode E1 of the driving component D, and the second electrode 211 of the electronic component 20(G) is electrically connected to the first electrode E1 of the driving component D through the opening H1 of the first optical adjustment unit 12. According to some embodiments, the reflection caused by the first electrode E1 of the driving component D may be reduced so as to reduce the glare of the electronic device 1 thereby improving the display quality. With the arrangement of the first optical adjustment unit 12 and the second optical adjustment unit 12′, the glare of the electronic device 1 may be reduced, thereby improving the display quality. More specifically, when light enters materials with different refractive indices, the destructive interference generated between the reflected light will reduce the reflectivity, thereby reducing the glare of the electronic device 1 and improving the display quality. Therefore, in the present disclosure, the refractive index of the insulation layer 121 may be between the refractive index of the first electrode E1 and the refractive index of the metal layer 122. In one embodiment of the present disclosure, the first optical adjustment unit 12 and/or the second optical adjustment unit 12′ may be in direct contact with the source-drain layer 117. More specifically, the first optical adjustment unit 12 and/or the second optical adjustment unit 12′ may be in direct contact with the first electrode E1 and/or the third electrode E2 of the source-drain layer 117. In addition, the metal layer 122 of the first optical adjustment unit 12 and/or the second optical adjustment unit 12′ may also be in direct contact with the insulation layer 121.

In the present disclosure, the material of the insulation layer 121 may include silicon oxide, silicon nitride, silicon oxynitride, or a combination thereof, but the present disclosure is not limited thereto. The material of the metal layer 122 may include titanium, nickel, molybdenum, copper, an alloy thereof, or a combination thereof, but the present disclosure is not limited thereto. In addition, the thickness ratio of the insulation layer 121 to the metal layer 122 may be between 2 and 100 (2≤thickness ratio≤100); for example, it may be between 3 and 90 (3≤thickness ratio≤90), between 3 and 70 (3≤thickness ratio≤70), or between 3 and 50 (3≤thickness ratio 50), but the present disclosure is not limited thereto. The thickness of the insulation layer 121 may be between 10 nanometers (nm) and 500 nanometers (nm) (10 nm≤insulation layer thickness≤500 nm); for example, it may be between 10 nanometers and 400 nanometers (10 nm≤insulation layer thickness≤300 nm), between 10 nm and 300 nm (10 nm≤insulation layer thickness≤300 nm), between 30 nm and 150 nm (30 nm≤insulation layer thickness≤150 nm), or between 60 nm and 100 nm (60 nm≤insulation layer thickness≤100 nm), but the present disclosure is not limited thereto. In addition, the thickness of the metal layer 122 may be between 1 nanometer (nm) and 100 nanometers (nm) (1 nm≤metal layer thickness≤100 nm); for example, it may be between 1 nanometer and 80 nanometers (1 nm≤metal layer thickness≤80 nm), between 1 nm and 50 nm (1 nm≤metal layer thickness≤50 nm), between 3 nm and 35 nm (3 nm≤metal layer thickness≤35 nm), or between 7 nm and 18 nm (7 nm≤metal layer thickness≤18 nm), but the present disclosure is not limited thereto. By adjusting the thickness of the insulation layer 121 and/or the metal layer 122, the glare of the electronic device 1 may be further reduced.

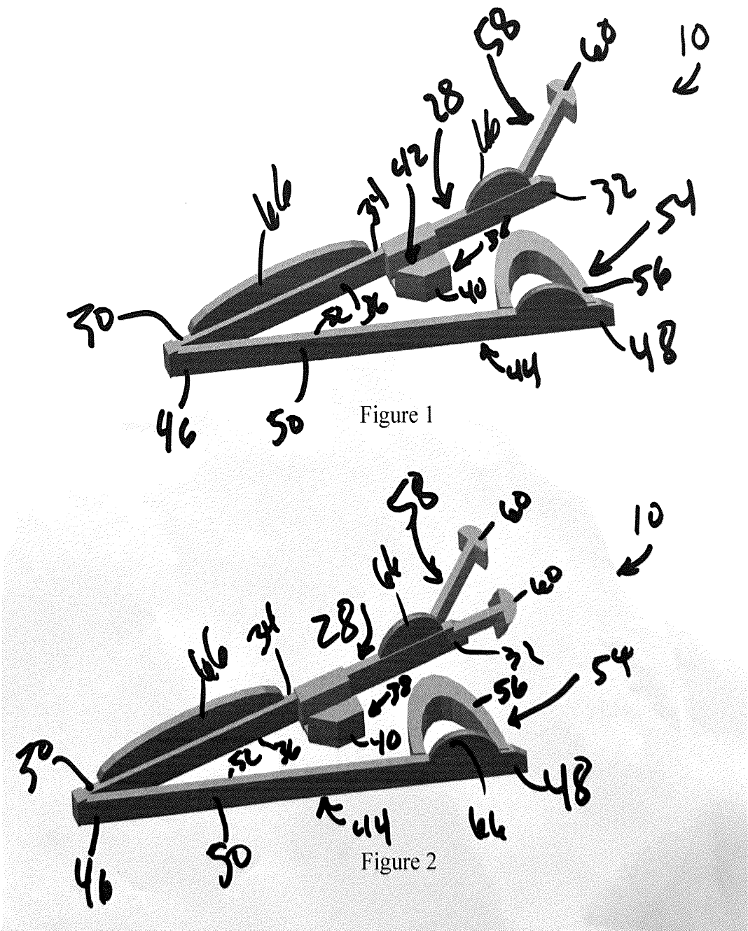

FIG. 2 is a cross-sectional view of the electronic device according to another embodiment of the present disclosure, wherein the electronic device of FIG. 2 is similar to that of FIG. 1B except for the following differences.

As shown in FIG. 2, in this embodiment, the first electrode E1 may include a first sidewall 1172, and the first sidewall 1172 is connected to the surface 1171 of the first electrode E1, wherein the insulation layer 121 may cover the first sidewall 1172 of the electrode E1. In addition, the insulation layer 121 may include a second sidewall 1212, and the second sidewall 1212 is connected to the surface 1211 of the insulation layer 121. According to some embodiments, the metal layer 122 may cover the second sidewall 1212 of the insulation layer 121. Similarly, the third electrode E2 may be designed similar to the first electrode E1, and thus a detailed description is deemed unnecessary. After the light enters the electronic device 1, the light may also pass through the sidewall of the source-drain layer 117 to generate reflected light. Therefore, when designing that the insulation layer 121 covers the first sidewall 1172 of the first electrode E1 or/and the metal layer 122 covers the second sidewall 1212 of the insulation layer 121, the generation of reflected light may be further reduced, thereby reducing the glare of the electronic device 1.

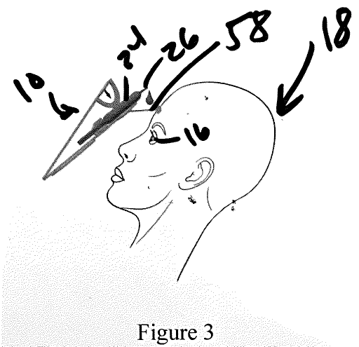

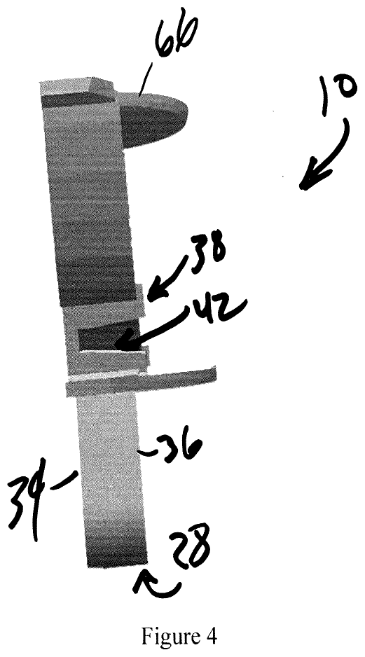

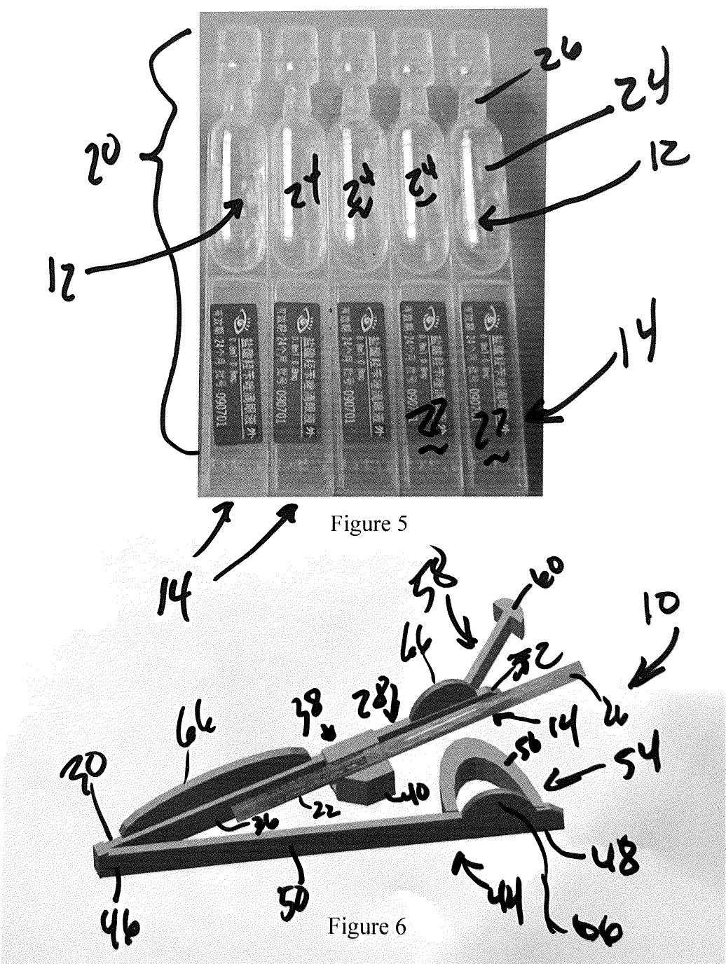

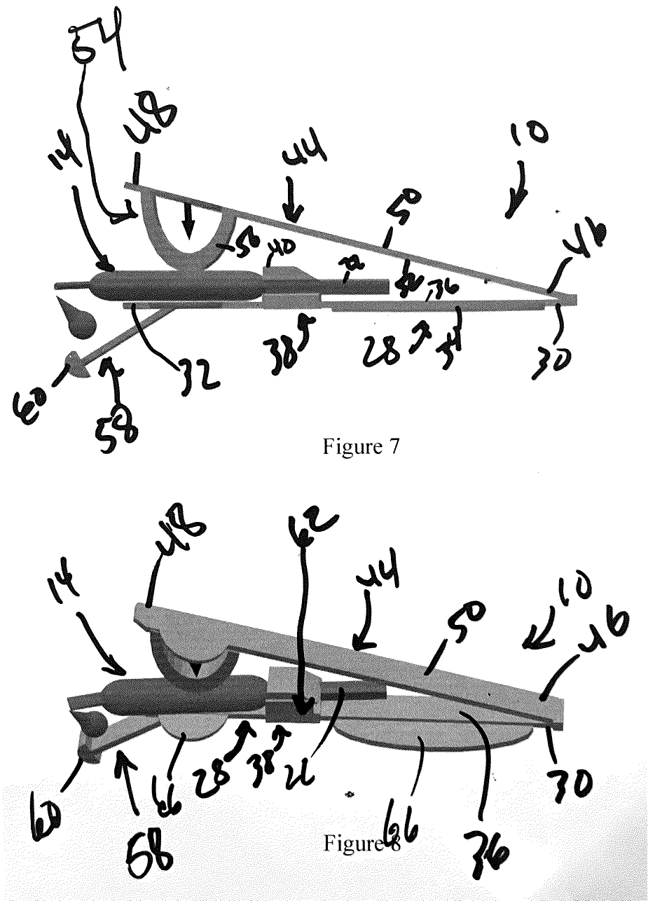

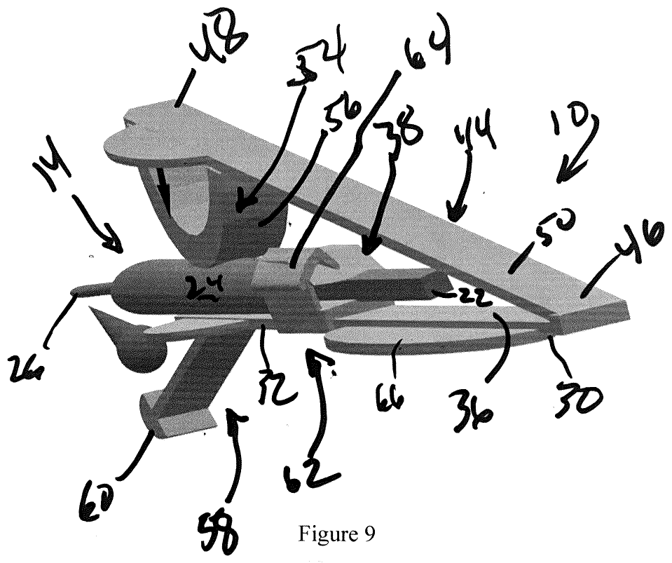

FIG. 3 shows the reflectivity analysis results for the combination structure of the first electrode E1 and the first optical adjustment unit 12 according to an embodiment of the present disclosure.

By using the combination structure of the first electrode E1 and the first optical adjustment unit 12 as shown in FIG. 1B, a simulation analysis is performed on the reflectivity, and the analysis results are shown in FIG. 3, wherein the material of the first electrode E1 is molybdenum/aluminum/molybdenum (Mo/Al/Mo), the first optical adjustment unit 12 includes an insulation layer 121 and a metal layer 122, the material of the insulation layer 121 is silicon dioxide, the material of the metal layer 122 is titanium (Ti), and the simulated light wavelength is 650 nm.

As shown in FIG. 3, the horizontal ordinate indicates the thickness of the insulation layer 121 (titanium), and the vertical ordinate indicates the thickness of the metal layer 122 (silicon dioxide). When the thicknesses of the insulation layer 121 and the metal layer 122 are each within a specific range, the reflectivity can be reduced to be smaller than or equal to 0.2%. For the specific range, for example, the thickness of the insulation layer 121 may be between 50 nm and 140 nm (50 nm≤insulation layer thickness 140 nm), and the thickness of the metal layer 122 may be between 3 nm and 33 nm (3 nm≤metal layer thickness≤33 nm). In addition, when the thickness ranges of the insulation layer 121 and the metal layer 122 are further limited, the reflectivity may be further reduced to be smaller than or equal to 0.1%. For example, the thickness of the insulation layer 121 may be between 60 nm and 130 nm (60 nm≤insulation layer thickness≤130 nm), and the thickness of the metal layer 122 may be between 7 nm and 18 nm (7 nm≤metal layer thickness≤18 nm).

In summary, in the electronic device of the present disclosure, the optical adjustment unit is arranged on the first electrode of the driving component, and the second electrode of the electronic component is electrically connected to the first electrode of the driving component through the opening of the optical adjustment unit. According to some embodiments, the reflection caused by the first electrode of the driving component may be reduced so as to reduce the glare of the electronic device thereby improving the display quality.

The aforementioned specific embodiments should be construed as merely illustrative, and not limiting the rest of the present disclosure in any way.

1. An electronic device, comprising:
a substrate;
a driving component arranged on the substrate, wherein the driving component includes a first electrode and a first optical adjustment unit, the first optical adjustment unit is arranged on the first electrode, and the first optical adjustment unit has a first opening to expose a surface of the first electrode; and
an electronic component arranged on the driving component, wherein the electronic component includes a second electrode electrically connected to the first electrode of the driving component through the first opening of the first optical adjustment unit.

2. The electronic device as claimed in claim 1, wherein the first optical adjustment unit includes a metal layer and an insulation layer, and the insulation layer is arranged between the first electrode and the metal layer.

3. The electronic device as claimed in claim 2, wherein the insulation layer covers a first sidewall of the first electrode.

4. The electronic device as claimed in claim 3, wherein the metal layer covers a second sidewall of the insulation layer.

5. The electronic device as claimed in claim 2, wherein a thickness ratio of the insulation layer to the metal layer is between 2 and 100.

6. The electronic device as claimed in claim 5, wherein the thickness ratio of the insulation layer to the metal layer is between 3 and 50.

7. The electronic device as claimed in claim 2, wherein a material of the metal layer includes titanium, nickel, molybdenum, copper, an alloy thereof, or a combination thereof.

8. The electronic device as claimed in claim 2, wherein a material of the insulation layer includes silicon oxide, silicon nitride, silicon oxynitride, or a combination thereof.

9. The electronic device as claimed in claim 2, wherein a thickness of the metal layer is between 1 nanometer and 100 nanometers.

10. The electronic device as claimed in claim 2, wherein a thickness of the insulation layer is between 10 nanometers and 500 nanometers.

11. The electronic device as claimed in claim 1, wherein the driving component further includes a third electrode and a second optical adjustment unit, the second optical adjustment unit includes an insulation layer arranged between the third electrode and the metal layer, and a metal layer.

12. The electronic device as claimed in claim 11, further comprising a passivation layer arranged on the first optical adjustment unit and the second optical adjustment unit.

13. The electronic device as claimed in claim 12, further comprising a pixel definition layer arranged on the passivation layer and the second electrode and provided with a second opening to expose part of the second electrode.

14. The electronic device as claimed in claim 13, wherein the electronic component further includes a light emitting layer and a fourth electrode, and the light emitting layer is arranged between the second electrode and the fourth electrode.

15. The electronic device as claimed in claim 14, wherein one of the second electrode and the fourth electrode is an anode, and the other one is a cathode.

16. The electronic device as claimed in claim 14, wherein the light emitting layer is disposed in the second opening and arranged on the second electrode, and the fourth electrode is arranged on the light emitting layer.

17. The electronic device as claimed in claim 14, wherein an area of the fourth electrode is larger than an area of the second electrode.

18. The electronic device as claimed in claim 2, wherein a refractive index of the insulation layer is between a refractive index of the first electrode and a refractive index of the metal layer.

19. The electronic device as claimed in claim 3, wherein the first sidewall is connected to the surface of the first electrode.

20. The electronic device as claimed in claim 4, wherein the second sidewall is connected to a surface of the insulation layer.
